(19) United States
(12) Patent Application Publication
(10) Pub. No.: US 2014/0022465 A1
(43) Pub. Date: Jan. 23, 2014

(54) COLOR FILTER SUBSTRATE, TOUCH DISPLAY PANEL AND TOUCH DISPLAY DEVICE

(71) Applicant: Tianjin Funayuanchuang Technology Co., Ltd., Tianjin (CN)

(72) Inventor: HO-CHIEN WU, New Taipei (TW)

(73) Assignee: TIANJIN FUNAYUANCHUANG TECHNOLOGY CO.,LTD., Tianjin (CN)

(21) Appl. No.: 13/948,172

(22) Filed: Jul. 23, 2013

(30) Foreign Application Priority Data
Jul. 23, 2012 (CN) 2012102544364

(51) Int. Cl. H03K 17/96; G02F 1/1333

(52) U.S. Cl. CPC H03K 17/9622; G02F 1/13338; B82Y 15/00
USPC 349/12; 200/600; 977/932

(57) ABSTRACT

A color filter substrate for a touch display panel includes a common electrode layer and a transparent conductive layer. The common electrode layer includes a plurality of common electrodes each extending along a first direction. The transparent conductive layer exhibits electric anisotropy and has the lowest resistivity along a second direction. The transparent conductive layer and the common electrode layer cooperatively define a capacitive touch sensitive structure.

### CROSS-REFERENCE TO RELATED APPLICATIONS

This application claims all benefits accruing under 35 U.S.C. §119 from China Patent Application No. 201210254436.4, filed on Jul. 23, 2012 in the China Intellectual Property Office, the content of which is hereby incorporated by reference. This application is related to commonly-assigned applications entitled, “POLARIZER”, U.S. application Ser. No. 13/730,711, filed Dec. 28, 2012; “POLARIZER”, U.S. application Ser. No. 13/730,884, filed Dec. 29, 2012, “LIQUID CRYSTAL DISPLAY MODULE”, U.S. application Ser. No. 13/837,266, filed Mar. 15, 2013, and “LIQUID CRYSTAL DISPLAY MODULE”, U.S. application Ser. No. 13/837,359 filed Mar. 15, 2013; “LIQUID CRYSTAL DISPLAY MODULE”, U.S. application Ser. No. 13/869,958, filed Apr. 25, 2013, and “LIQUID CRYSTAL DISPLAY MODULE”, U.S. application Ser. No. 13/869,959 filed Apr. 25, 2013; “METHOD FOR MAKING LIQUID CRYSTAL DISPLAY MODULE”, U.S. application Ser. No. 13/869,961, filed Apr. 25, 2013; “METHOD FOR MAKING LIQUID CRYSTAL DISPLAY MODULE”, U.S. application Ser. No. 13/869,964, filed Apr. 25, 2013, and “COLOR FILTER SUBSTRATE AND TOUCH DISPLAY PANEL USING SAME” filed **** (Atty. Docket No. US46697).

### BACKGROUND

1. Technical Field

The present disclosure relates to a color filter substrate, a touch display panel and a touch display device using the same.

2. Description of Related Art

Touch display panels and devices usually have a color filter substrate and a touch screen attached to the color filter substrate via optical clear adhesive. However, because of the optical clear adhesive, a thickness of the touch display panels and devices is hard to reduce. Thus, the touch display panels and devices may be not meet users' requirements.

What is needed is to provide a means that can overcome the above-described limitations.

### BRIEF DESCRIPTION OF THE DRAWINGS

The components in the drawings are not necessarily drawn to scale, the emphasis instead being placed upon clearly illustrating the principles of at least one embodiment. In the drawings, like reference numerals designate corresponding parts throughout the various views.

FIG. 1 is a schematic view of a touch display panel according to an embodiment of the present disclosure, the touch display panel including a first substrate and a second substrate.

FIG. 2 is an exploded view of the first substrate of the touch display panel of FIG. 1, the first substrate including a common electrode layer and a transparent conductive layer.

FIG. 3 is a schematic view of a carbon nanotube conductive layer configured to form an example transparent conductive layer of FIG. 2.

FIG. 4 is a circuit diagram of a driving layer of the second substrate of the touch display panel of FIG. 1.

FIG. 5 shows a relationship of the common electrode layer of FIG. 2 and the driving layer of FIG. 4.

FIG. 6 shows waveforms of touch scanning signals applied to the common electrode layer of FIG. 2.

FIG. 7 shows waveforms of common voltage signals applied to the common electrode layer of FIG. 2.

FIG. 8 is a block diagram of a touch display device according to an embodiment of the present disclosure.

### DETAILED DESCRIPTION

Reference will now be made to the drawings to describe various embodiments in detail.

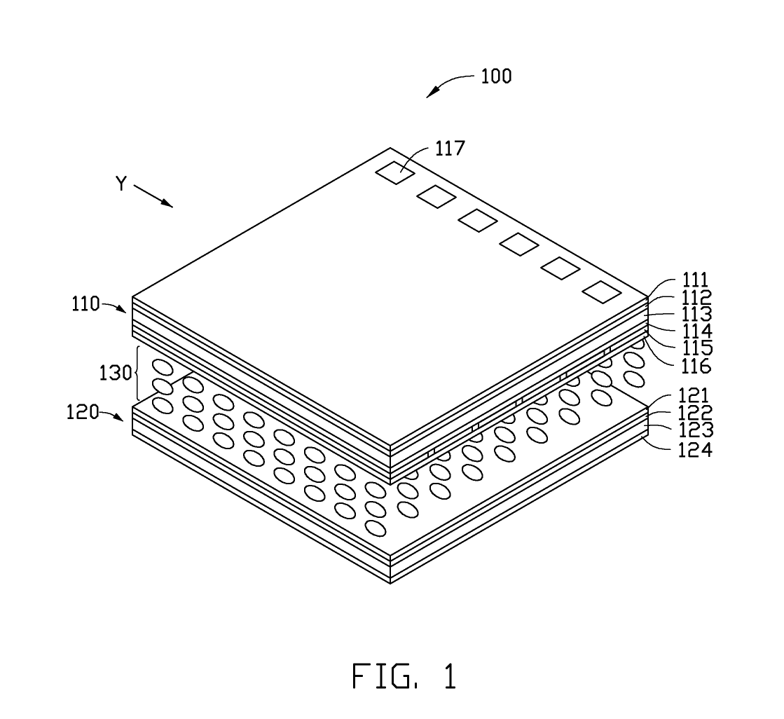

Referring to FIG. 1, a touch display panel 100 according to an embodiment of the present disclosure includes a first substrate 110, a second substrate 120 facing the first substrate 110, and a liquid crystal layer 130 sandwiched between the first substrate 110 and the second substrate 120. The first substrate 110 can be a color filter substrate and includes a transparent conductive layer 111, an upper polarizer 112, a first base 113, a color filter layer 114, a common electrode layer 115, an upper orientation layer 116, and a plurality of sensitive electrodes 117. The second substrate 120 includes a lower orientation layer 121, a driving layer 122, a second base 123, and a lower polarizer 124.

The first base 113 can be a glass substrate, a side of the first base 113 adjacent to the liquid crystal layer 130 is defined as a first side of the first base 113, and a side of the first base 113 away from the liquid crystal layer 130 is defined as a second side of the first base 113. The upper polarizer 112 and the transparent conductive layer 111 are located on a first side of the first base 113. In one embodiment, the upper polarizer 112 is located on a surface of the first base 113 away from the liquid crystal layer 130, and the transparent conductive layer 111 is located on a side of the upper polarizer 112 away from the liquid crystal layer 130.

In the embodiment, the color filter layer 114, the common electrode layer 115, and the upper orientation layer 116 are located on the second side of the first base 113. In an alternative embodiment, the color filter layer 114 can be located on the first side of the substrate 113 and is sandwiched between the upper polarizer 112 and the first base 113. Referring to FIG. 1, the color filter layer 114 is located on a surface of the first base 113 adjacent to the liquid crystal layer 130, the common electrode layer 115 is located on a side of the color filter layer 114 adjacent to the liquid crystal layer 130, and the upper orientation layer 116 is located on a side of the common electrode layer 115 adjacent to the liquid crystal layer 130. The sensitive electrodes 117 are located on a side of the transparent conductive layer 111 away from the upper polarizer 112, and the plurality of sensitive electrodes 117 are arranged along the a first direction Y. The sensitive electrodes 117 are electrically connected to the transparent conductive layer 111 and configured to electrically couple to a touch sensitive circuit.

The second base 123 can be a glass substrate. The driving layer 122 can be a thin film transistor driving layer and is configured to cooperate with the common electrode layer 115 to drive the liquid crystal layer 130. The lower orientation layer 121 and the driving layer 122 are located on a side of the second base 123 adjacent to the liquid crystal layer 130. In the embodiment, the driving layer 122 is located on a surface of the second base 123 adjacent to the liquid crystal layer 130, and the lower orientation layer 121 is located on a side of the driving layer 122 adjacent to the liquid crystal layer 130. The lower polarizer 124 is attached to a surface of the second base 123 away from the liquid crystal layer 130.

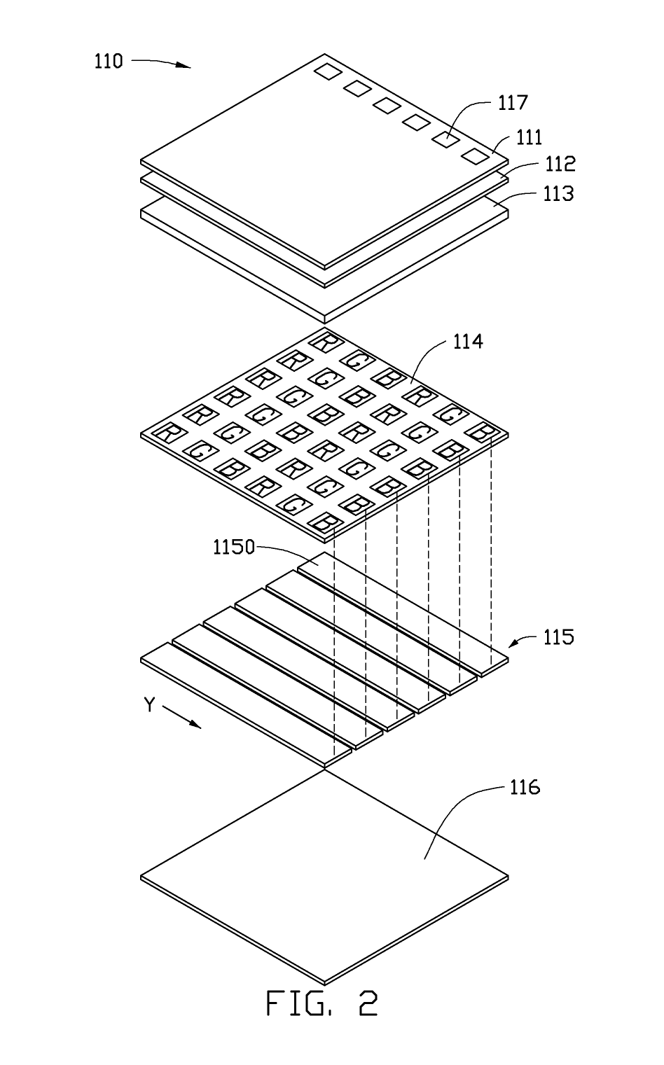

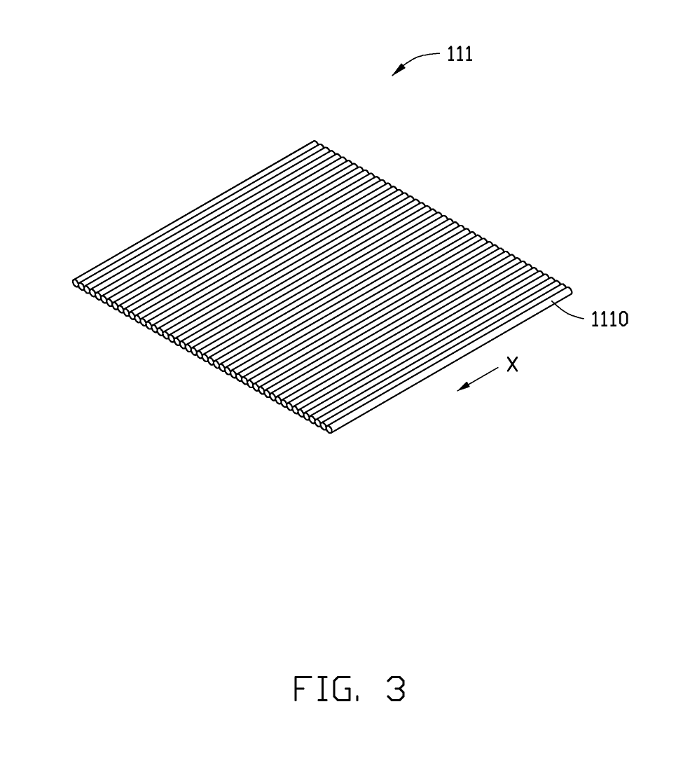

Referring to FIG. 2, the transparent conductive layer 111 is continuous conductive layer. The transparent conductive layer 111 exhibits electric anisotropy and has the lowest resistivity along a second direction X perpendicular to the first direction Y. In the embodiment, the transparent conductive layer 111 is a carbon nanotube (CNT) film. Referring to FIG. 3, the carbon nanotube (CNT) film includes a plurality of carbon nanotubes 1110 orderly arranged along the second direction X. Each carbon nanotube 1110 is attached to the adjacent carbon nanotube 1110 by waals forces. The transparent conductive layer 111 may be attached to the upper polarizer 112 first, then both the upper polarizer 112 and the transparent conductive layer 111 as one body are attached to the surface of the first base 113 away from the liquid crystal layer 130.

The common electrode layer 115 includes plurality of common electrodes 1150 each extending along the first direction Y. In the embodiment, the common electrode layer 115 is configured to cooperate with the driving layer 122 to drive the liquid crystal layer 130, and the common electrode layer 115 is also configured to cooperate with the transparent conductive layer 111 to define a capacitive touch sensitive structure. A dielectric layer of the capacitive touch sensitive structure includes the first base 113, the upper polarizer 112, and the color filter layer 114. In an alternative embodiment, the color filter layer is located between the common electrode layer 115 and the upper polarizer 112, such that a dielectric layer of the capacitive touch sensitive structure includes the first base 113 and the upper polarizer 112. The common electrode layer 115 can be made of a material selected from the group consisting of indium tin oxide or indium zinc oxide.

The color filter layer 114 includes a plurality of filter units arranged in a matrix. The plurality of filter units includes red filter units R, green filter units G, and blue filter units B. In the embodiment, each row of the filter units superposes a corresponding one common electrode 1150 along a direction perpendicular to the color filter substrate 110.

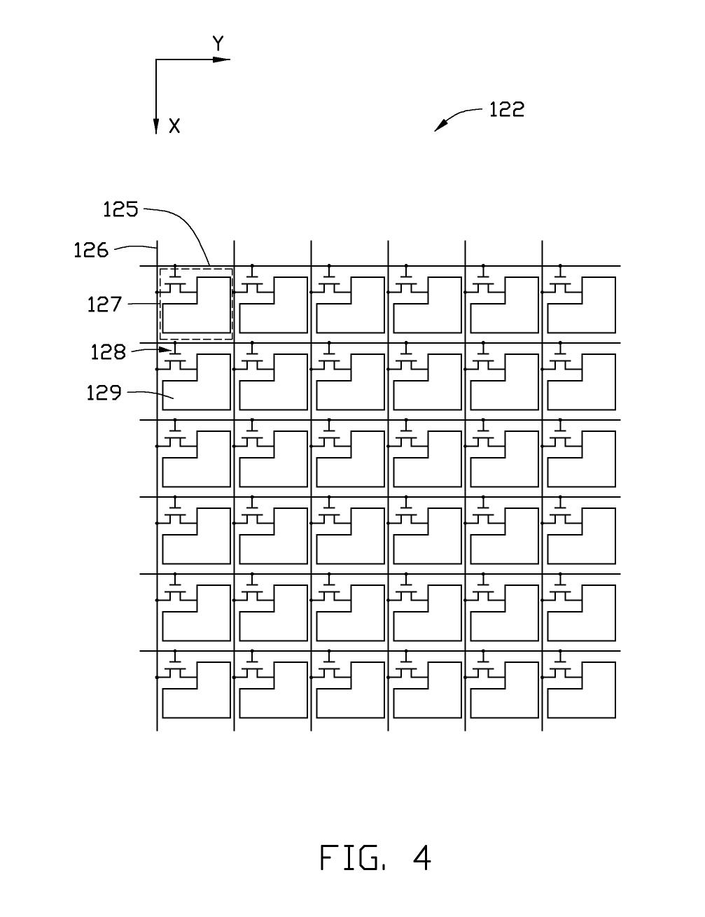

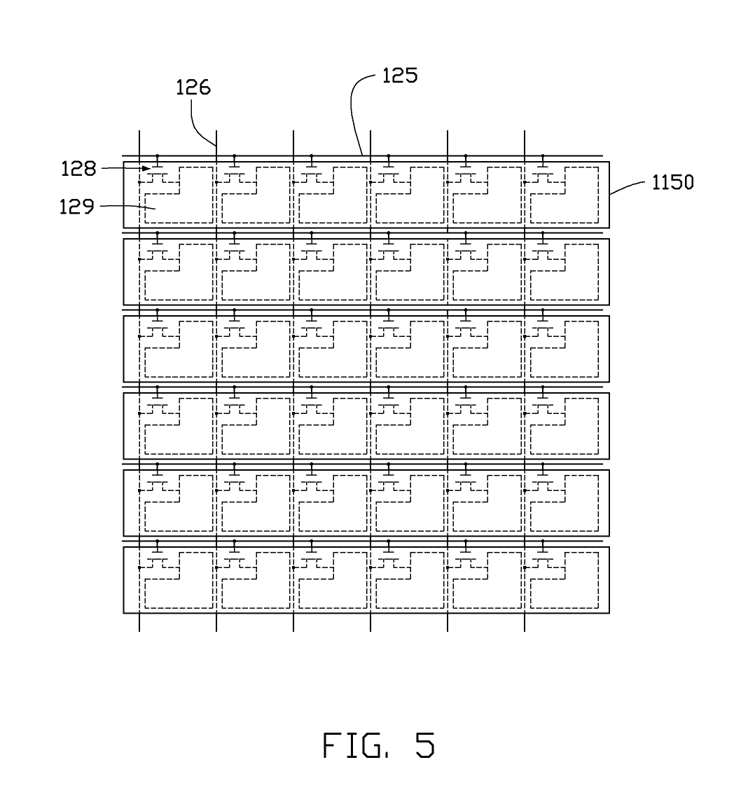

Referring to FIG. 4, the driving layer 122 includes a plurality of gate lines 125 extending along the first direction Y, a plurality of data lines 126 extending along the second direction X, and a plurality of pixel regions 127 defined by the gate line 125 crossing the data lines 126. The plurality of pixel regions 127 are arranged in a matrix corresponding to the matrix of the filter units of the color filter layer 114. Each pixel region 127 includes a thin film transistor 128 and a pixel electrode 129 electrically coupled to the thin film transistor 128. Referring to FIG. 5, in one embodiment, each common electrode 1150 superposes a corresponding one row of pixel regions 127 along a direction perpendicular to the touch display panel 100.

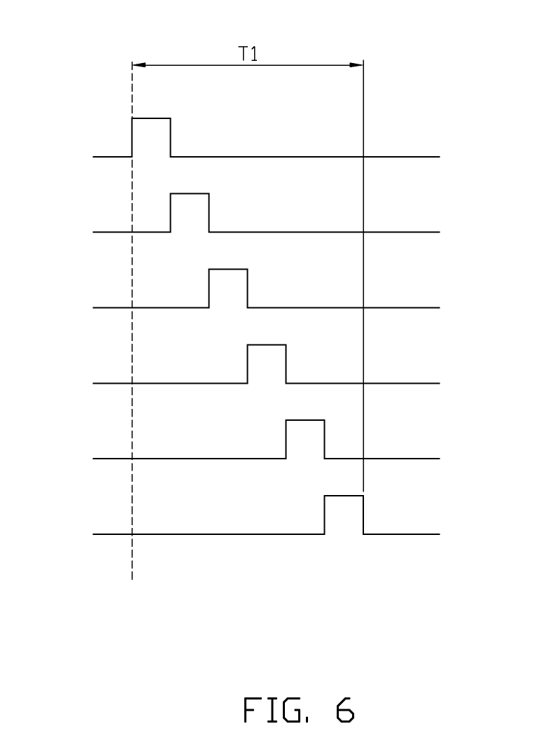

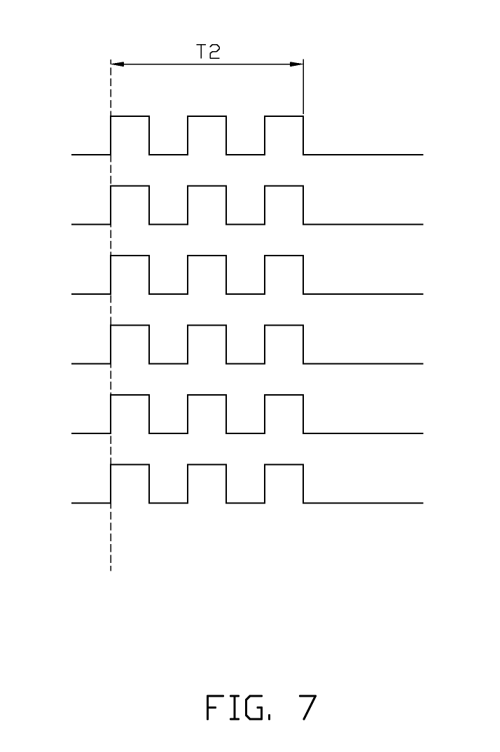

Referring to FIG. 6 and FIG. 7, in operation, the common electrode 1150 are applied with a common voltage and touch scanning signals alternatively. The touch display panel 100 works in a touch sensitive period T1 and a display period T2 alternatively. When the touch display panel 100 works in the display period T1, the common electrodes 1150 are applied with an alternating common voltage simultaneously, and when the touch display panel 100 works in the touch sensitive period T2, the common electrodes 1150 are applied with a plurality of scanning voltage in series. Furthermore, to improve dynamic display quality of the touch display panel 100, when the touch display panel 100 is works in the touch sensitive period, the touch display panel 100 displays a black image.

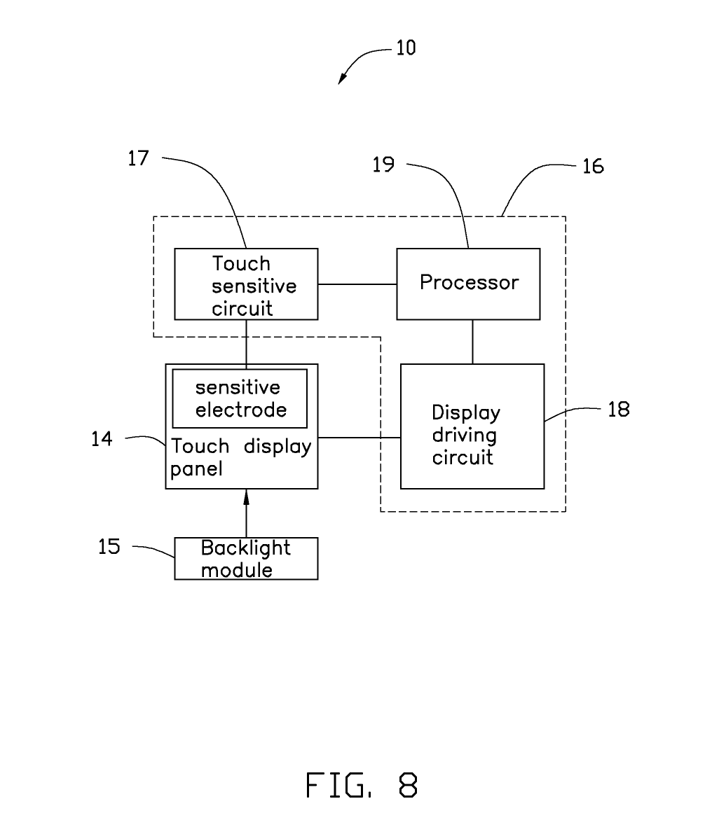

Referring to FIG. 8, a touch display device 10 includes a touch display panel 14, a backlight module 15, and a driving circuit 16. The backlight module 15 is configured to provide planar light to the touch display panel 14. The driving circuit 16 is configured to drive the touch display panel 14. The touch display panel 14 can be employed the touch display panel 10 as described above. The driving circuit 16 includes a display driving circuit 18, a touch sensitive circuit 17 and a processor 19. The display driving circuit 18 provides common voltage signals and pixel electrode signals to the touch display panel 14 to drive the touch display panel 14 to display images. The display driving circuit 18 further provides touch scanning signals to the touch display panel 14. The touch sensitive circuit 17 is configured to electrically connect to sensitive electrodes of the touch display panel 14 and detect voltage change of the sensitive electrodes of the touch display panel 14 to obtain positions of touch operation applied to the touch display panel 14.

In summary, the touch display panel 100 and the touch display device 10 has the capacitive touch sensitive structure directly formed on the first substrate 110, there is no need to provide optical clear adhesive to attach the capacitive touch sensitive structure on the first substrate 110, such that a thickness of the touch display panel 100 and the touch display device 10 can be reduced.

It is to be understood that even though numerous characteristics and advantages of the present embodiments have been set forth in the foregoing description, together with details of the structures and functions of the embodiments, the disclosure is illustrative only; and that changes may be made in detail, especially in matters of shape, size, and arrangement of parts, within the principles of the embodiments, to the full extent indicated by the broad general meaning of the terms in which the appended claims are expressed.

What is claimed is:

1. A color filter substrate for a touch display panel, comprising:
a common electrode layer comprising a plurality of common electrodes each extending along a first direction; and
a transparent conductive layer exhibiting electric anisotropy and having the lowest resistivity along a second direction, and the transparent conductive layer and the common electrode layer cooperatively defining a capacitive touch sensitive structure.

2. The color filter substrate of claim 1, wherein the common electrode layer comprises material selected from the group consisting of indium tin oxide or indium zinc oxide.

3. The color filter substrate of claim 1, wherein the first direction is perpendicular to the second direction.

4. The color filter substrate of claim 1, wherein the transparent conductive layer comprises a carbon nanotube (CNT) film comprising a plurality of carbon nanotubes orderly arranged along the second direction.

5. The color filter substrate of claim 1, further comprising a base, wherein the common electrode layer is located on a first side of the base, and the transparent conductive layer is located on a second side opposite to the first side of the base.

6. The color filter substrate of claim 1, further comprising a polarizer located between the base and the transparent conductive layer, such that a dielectric layer of the capacitive touch sensitive structure comprises the base and the polarizer.

7. The color filter substrate of claim 6, further comprising a color filter layer located between the base and the common electrode layer, such that the dielectric layer of the capacitive touch sensitive structure further comprises a color filter layer.

8. The color filter substrate of claim 7, wherein the color filter layer comprising a plurality of filter units arranged in a matrix, and each rows of the filter units superposes a corresponding one common electrode along a direction perpendicular to the color filter substrate.

9. A touch display panel, comprising:
a first substrate comprising:
a common electrode layer comprising a plurality of common electrodes each extending along a first direction; and
a transparent conductive layer exhibiting electric anisotropy and having the lowest resistivity along a second direction, and the transparent conductive layer and the common electrode layer cooperatively defining a capacitive touch sensitive structure;
a second substrate; and
a liquid crystal layer sandwiched between the first substrate and the second substrate.

10. A touch display device, comprising:
a touch display panel comprising:
a first substrate comprising:
a common electrode layer comprising a plurality of common electrodes each extending along a first direction; and
a transparent conductive layer exhibiting electric anisotropy and having the lowest resistivity along a second direction, and the transparent conductive layer and the common electrode layer cooperatively defining a capacitive touch sensitive structure;
a second substrate; and
a liquid crystal layer sandwiched between the first substrate and the second substrate;
a backlight module for providing light beams to the touch display panel; and
a driving circuit for driving the touch display panel.

11. The touch display device of claim 10, wherein the common electrode layer comprises material selected from the group consisting of indium tin oxide or indium zinc oxide.

12. The touch display device of claim 10, wherein the first direction is perpendicular to the second direction.

13. The touch display device of claim 10, wherein the transparent conductive layer comprises a carbon nanotube (CNT) film comprising a plurality of carbon nanotubes orderly arranged along the second direction.

14. The touch display device of claim 10, wherein the first substrate further comprises a base, the common electrode layer is located on a first side of the base, and the transparent conductive layer is located on a second side opposite to the first side of the base.

15. The touch display device of claim 14, wherein the first substrate further comprises a polarizer located between the base and the transparent conductive layer, such that a dielectric layer of the capacitive touch sensitive structure comprises the base and the polarizer.

16. The touch display device of claim 15, wherein the first substrate further comprises a color filter layer located between the base and the common electrode layer, such that the dielectric layer of the capacitive touch sensitive structure further comprises a color filter layer.

17. The touch display device of claim 10, wherein the second substrate comprises a plurality of gate lines, a plurality of data lines, and a plurality of pixel regions defined by the gate line and the data lines, the plurality of pixel regions are arranged in a matrix, and each common electrode superposes a corresponding one row of pixel regions.

18. The touch display device of claim 10, further comprising a touch sensitive circuit, wherein the first substrate further comprises a plurality of sensitive electrodes electrically connected to the transparent conductive layer, the common electrodes are applied with a common voltage and touch scanning signals alternatively, the touch sensitive circuit is electrically coupled to the sensitive electrodes and detects voltage change of the sensitive electrodes to obtain positions of touch operation applied to the capacitive touch sensitive structure.

19. The touch display device of claim 10, wherein the touch display device has a touch sensitive period and a display period, when the touch display device is in the display period, the common electrodes are applied with an alternating common voltage simultaneously, and when the touch display device is in the touch sensitive period, the common electrodes are applied with a plurality of scanning voltage in series.

20. The touch display device of claim 19, wherein the touch display device is in the touch sensitive period, the touch display panel displays a black image.
